(19) United States
(12) Patent Application Publication
(10) Pub. No.: US 2025/0386511 A1
(43) Pub. Date: Dec. 18, 2025

(54) SEMICONDUCTOR DEVICE, ELECTRONIC SYSTEM INCLUDING THE SAME, AND METHOD FOR MANUFACTURING THE SAME

(71) Applicant: Samsung Electronics Co., Ltd., Suwon-si (KR)

(72) Inventors: Hyouk-Sang YUN, Suwon-si (KR); Se Jun PARK, Suwon-si (KR)

(73) Assignee: Samsung Electronics Co., Ltd., Suwon-si (KR)

(21) Appl. No.: 19/015,904

(22) Filed: Jan. 10, 2025

(30) Foreign Application Priority Data
Jun. 17, 2024 (KR) 10-2024-0078513

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device is provided. The semiconductor device comprises a substrate, a gate electrode on the substrate, a gate insulating film between the substrate and the gate electrode, a trench defined within the substrate, the gate insulating film, and the gate electrode, a liner film within the trench and extending along at least a portion of a side surface of the gate insulating film, wherein the liner film is spaced apart from a lower surface of the trench, and an insulating layer filling the trench and covering an upper surface of the gate electrode, wherein the gate insulating film includes a first portion spaced apart from the liner film and a second portion adjacent to the liner film, wherein a thickness of the second portion is greater than a thickness of the first portion.

### CROSS-REFERENCE TO RELATED APPLICATION

This application claims priority from Korean Patent Application No. 10-2024-0078513 filed on Jun. 17, 2024 in the Korean Intellectual Property Office, and all the benefits accruing therefrom under 35 U.S.C. 119, the contents of which in its entirety are herein incorporated by reference.

### BACKGROUND

The present disclosure relates to semiconductor devices, electronic systems including the same, and/or methods for manufacturing the same.

As an electronic product become lighter, thinner, and simpler, the demand for high integration of a semiconductor device is increasing. As the semiconductor device become more highly integrated, sizes of components included in the semiconductor device (e.g., a transistor) further decrease, thereby causing a problem of leakage current. Therefore, it may be advantageous control the leakage current of the semiconductor device to improve performance and/or reliability of the semiconductor device.

In an electronic system that requires data storage, a semiconductor device that may store high-capacity data therein may be advantageous. Accordingly, a scheme to increase the data storage capacity of the semiconductor device is being studied. For example, in one approach to increase the data storage capacity of the semiconductor device, a semiconductor device including three-dimensionally arranged memory cells instead of two-dimensionally arranged memory cells has been proposed.

### SUMMARY

One technical purpose of the present disclosure is to provide a semiconductor device with improved reliability and/or performance.

Another technical purpose of the present disclosure is to provide an electronic system including a semiconductor device with improved reliability and/or performance.

The technical purposes of the present disclosure are not limited to the technical purposes as mentioned above, and other technical purposes not mentioned will be clearly understood by those skilled in the art from the description as set forth below.

According to an aspect of the present disclosure, there may be provided a semiconductor device comprising a substrate, a gate electrode on the substrate, a gate insulating film between the substrate and the gate electrode, a trench defined within the substrate, the gate insulating film, and the gate electrode, a liner film within the trench and extending along at least a portion of a side surface of the gate insulating film, wherein the liner film is spaced apart from a lower surface of the trench, and an insulating layer filling the trench and covering an upper surface of the gate electrode, wherein the gate insulating film includes a first portion spaced apart from the liner film and a second portion adjacent to the liner film, wherein a thickness of the second portion is greater than a thickness of the first portion.

According to an aspect of the present disclosure, there may be provided a semiconductor device comprising a substrate including a first area and a second area, a first gate electrode on the first area, a first gate insulating film having a first thickness and between the substrate and the first gate electrode, a first trench defined within the substrate, the first gate insulating film, and the first gate electrode, a liner film within the first trench, and extending along at least a portion of a side surface of the first gate insulating film, wherein the liner film is spaced apart from a lower surface of the first trench, a second gate electrode on the second area, a second gate insulating film between the substrate and the second gate electrode and having a second thickness smaller than the first thickness, a second trench defined within the substrate, the second gate insulating film, and the second gate electrode, and an insulating layer filling the first trench and the second trench and covering an upper surface of each of the first gate electrode and the second gate electrode, wherein a first depth of the first trench from on an upper surface of the first gate electrode to a bottom surface of the first trench is greater than a second depth of the second trench from on an upper surface of the second gate electrode to a bottom surface of the second trench.

According to an aspect of the present disclosure, there may be provided a semiconductor device comprising a main substrate, a semiconductor memory device on the main substrate and including a cell area and a peripheral circuit area, and a controller on the main substrate and electrically connected to the semiconductor memory device, wherein the semiconductor memory device includes: a first substrate in the cell area, a plurality of word-lines on the first substrate, and stacked on top of each other and spaced apart from each other, a channel structure extending in a vertical direction intersecting an upper surface of the first substrate so as to intersect the plurality of word-lines, a bit-line on the plurality of word-lines and connected to the channel structure, a second substrate in the peripheral circuit area, and a peripheral circuit element on the second substrate, wherein the peripheral circuit element includes: a gate electrode on the second substrate, a gate insulating film between the second substrate and the gate electrode, a trench defined within the second substrate, the gate insulating film, and the gate electrode, and a liner film within the trench and extending along at least a portion of a side surface of the gate insulating film, wherein the liner film is spaced apart from a lower surface of the trench.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail embodiments thereof with reference to the attached drawings, in which:

FIG. 1 is a layout diagram for illustrating a semiconductor device according to some example embodiments.

FIG. 2 is a schematic cross-sectional view taken along lines A-A, B-B, and C-C in FIG. 1.

FIG. 3 is an enlarged cross-sectional view of a P1 area in FIG. 2.

FIG. 4 is a schematic cross-sectional view cut along lines A-A, B-B, and C-C of FIG. 1 according to some example embodiments.

FIG. 5 is an enlarged cross-sectional view of a P2 area in FIG. 4.

FIG. 6 is a schematic cross-sectional view cut along lines A-A, B-B, and C-C of FIG. 1 according to still some example embodiments.

FIG. 7 is an enlarged cross-sectional view of a P3 area in FIG. 6.

FIG. 8 is a schematic cross-sectional view cut along lines A-A, B-B, and C-C of FIG. 1 according to some example embodiments.

FIGS. 9 to 17 are diagrams of intermediate structures corresponding to intermediate steps of a method for manufacturing a semiconductor device according to some example embodiments.

FIG. 18 is a schematic plan view for illustrating a non-volatile memory device according to some example embodiments of the technical idea of the present disclosure.

FIG. 19 is a block diagram for illustrating the non-volatile memory device in FIG. 18.

FIG. 20 is a schematic cross-sectional view for illustrating a non-volatile memory device according to some example embodiments.

FIG. 21 is a schematic block diagram for illustrating an electronic system according to some embodiments.

FIG. 22 is a schematic perspective view for illustrating an electronic system according to some example embodiments.

FIG. 23 shows various schematic cross-sectional views cut along a line I-I′ in FIG. 22.

### DETAILED DESCRIPTIONS

Although terms such as first, second, upper, and lower are used herein to describe various elements or components, it is obvious that these element or components are not limited by the terms. Rather, the terms are merely used herein to distinguish one element or component from another element or component. Therefore, it is obvious that a first element or component as mentioned below may also be a second element or component within the technical spirit of the present disclosure. Further, it is obvious that a lower element or component as mentioned below may also be an upper element or component within the technical spirit of the present disclosure.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

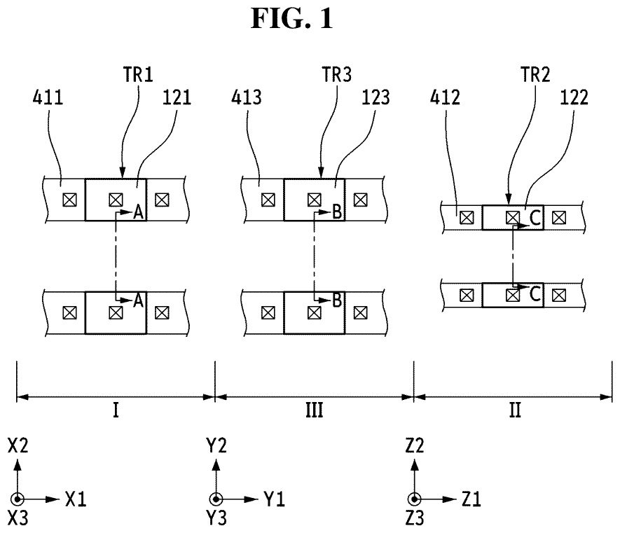

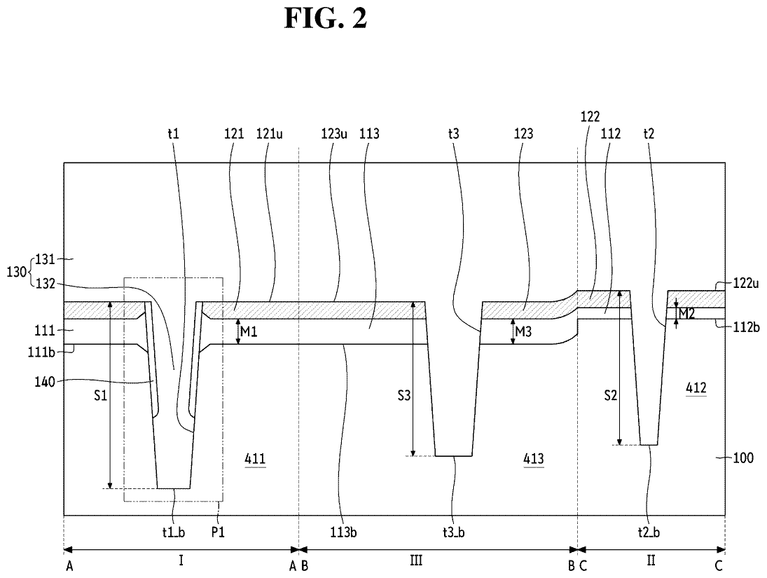

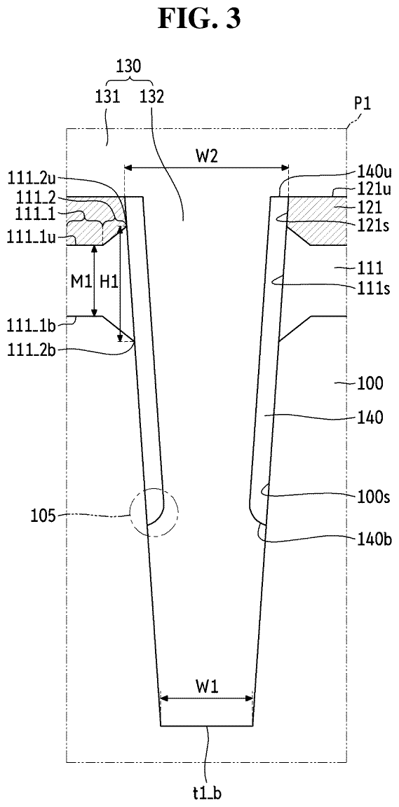

FIG. 1 is a layout diagram for illustrating a semiconductor device according to some example embodiments. FIG. 2 is a schematic cross-sectional view taken along lines A-A, B-B, and C-C in FIG. 1. FIG. 3 is an enlarged cross-sectional view of a P1 area in FIG. 2.

Referring to FIGS. 1 to 3, a semiconductor device according to some example embodiments may include a substrate 100, a plurality of circuit elements TR1, TR2 and TR3, a gate insulating film 111, 112 and 113, and a gate electrode 121, 122, and 123 and an insulating layer 130.

The substrate 100 may include, for example, a semiconductor substrate such as a silicon substrate, a germanium substrate, or a silicon-germanium substrate. Alternatively, the substrate 100 may include a Silicon-On-Insulator (SOI) substrate or a Germanium-On-Insulator (GOI) substrate.

The substrate 100 may include a first area I, a second area II, and a third area III to which different voltages are applied, respectively.

For example, the voltage applied to the third area III may be greater than the voltage applied to the second area II and may be smaller than the voltage applied to the first area I.

A first active area 411 may be formed on the first area I. A second active area 412 may be formed on the second area II. A third active area 413 may be formed on the third area III.

The plurality of circuit elements TR1, TR2 and TR3 may be formed on the substrate 100. For example, the plurality of circuit elements TR1, TR2 and TR3 may be formed on the active area 411, 412, and 413 of the substrate 100.

Hereinafter, an example in which each of the plurality of circuit elements TR1, TR2 and TR3 is embodied as a transistor is described. However, this is only an example and the technical idea of the present disclosure is not limited thereto. For example, the plurality of circuit elements TR1, TR2 and TR3 may include various active elements such as transistors, as well as various passive elements such as capacitors, resistors, and inductors.

In some example embodiments, each of the plurality of circuit elements TR1, TR2 and TR3 may be a high voltage transistor or a low voltage transistor.

The first gate electrode 121 may be formed on the first area I of the substrate 100. The first gate electrode 121 may be formed on the first active area 411 of the substrate 100. In FIG. 1, the first gate electrode 121 is shown extending in the second direction X2. However, this is only an example. The technical idea of the present disclosure is not limited thereto. For example, the first gate electrode 121 may extend in a direction different from the second direction X2.

The first gate electrode 121 may include a conductive material. In some example embodiments, the first gate electrode 121 may include a plurality of conductive films. The plurality of conductive films may include, for example, at least one of polysilicon or metal material.

The second gate electrode 122 may be formed on the second area II of the substrate 100. The second gate electrode 122 may be formed on the second active area 412 of the substrate 100. In FIG. 1, the second gate electrode 122 is shown extending in the second direction Z2. However, this is only an example. The technical idea of the present disclosure is not limited thereto. For example, the second gate electrode 122 may extend in a direction different from the second direction Z2.

The second gate electrode 122 may include a conductive material. In some example embodiments, the second gate electrode 122 may include a plurality of conductive films. The plurality of conductive films may include, for example, at least one of polysilicon or metal material.

The third gate electrode 123 may be formed on the third area III of the substrate 100. The third gate electrode 123 may be formed on the third active area 413 of the substrate 100. In FIG. 1, the third gate electrode 123 is shown extending in the second direction Y2. However, this is only an example. The technical idea of the present disclosure is not limited thereto. For example, the third gate electrode 123 may extend in a direction different from the second direction Y2.

The third gate electrode 123 may include a conductive material. In some example embodiments, the third gate electrode 123 may include a plurality of conductive films. The plurality of conductive films may include, for example, at least one of polysilicon or metal material.

The first active area 411 may be formed in the substrate 100 and each of on both opposing sides of the first circuit element TR1. The first active area 411 may be doped with impurities. For example, when the first circuit element TR1 is an n-type or p-type transistor, the first active area 411 may be doped with a p-type or n-type impurity.

The second active area 412 may be formed in the substrate 100 and on each of both opposing sides of the second circuit element TR2. The second active area 412 may be doped with impurities. For example, when the second circuit element TR2 is an n-type or p-type transistor, the second active area 412 may be doped with a p-type or n-type impurity.

The third active area 413 may be formed in the substrate 100 and on each of both opposing sides of the third circuit element TR3. The third active area 413 may be doped with impurities. For example, when the third circuit element TR3 is an n-type or p-type transistor, the third active area 413 may be doped with a p-type or n-type impurity.

The first circuit element TR1 may be disposed on the first area I. The first circuit element TR1 may include the first gate electrode 121 and the first gate insulating film 111. The second circuit element TR2 may be disposed on the second area II. The second circuit element TR2 may include the second gate electrode 122 and the second gate insulating film 112. The third circuit element TR3 may be disposed on the third area III. The third circuit element TR3 may include the third gate electrode 123 and the third gate insulating film 113.

In some example embodiments, each of the first circuit element TR1 and the third circuit element TR3 may be a high voltage transistor. For example, a high voltage of about 20V or higher may be applied to each of the first circuit element TR1 and the third circuit element TR3. However, some example embodiments of the present disclosure are not limited thereto.

In some example embodiments, the second circuit element TR2 may be a low-voltage transistor. For example, a low voltage of about 10V or lower may be applied to the second circuit element TR2. However, some example embodiments of the present disclosure are not limited thereto.

The first gate insulating film 111 may be disposed in the first area I of the substrate 100. The first gate electrode 121 may be disposed on the first gate insulating film 111. In other words, the first gate insulating film 111 may be disposed between the first gate electrode 121 and the substrate 100.

The first gate insulating film 111 may include a first portion 111_1 and a second portion 111_2. The first portion 111_1 may be spaced apart from the liner film 140, which will be described later. The second portion 111_2 may be disposed adjacent to the liner film 140.

The first portion 111_1 may have a first thickness M1. A thickness H1 of the second portion 111_2 may be greater than the first thickness M1 of the first portion 111_1. The thickness of the second portion 111_2 may increase as the second portion 111_2 extends toward the liner film 140. The lowermost surface 111_2b of the second portion 111_2 may be disposed between a lower surface 111_1b of the first portion 111_1 and a lower surface 140b of the liner film 140. The uppermost surface 111_2u of the second portion 111_2 may be disposed between an upper surface 111_1u of the first portion 111_1 and an upper surface 140u of the liner film 140.

The uppermost surface 111_2u of the second portion 111_2 may be disposed at a higher vertical level than a vertical level of the upper surface 111_1u of the first portion 111_1. The lowermost surface 111_2b of the second portion 111_2 may be disposed at a lower vertical level than a vertical level of the upper surface 111_1u of the first portion 111_1. For example, the second portion 111_2 may include a bird's beak shape.

The first gate insulating film 111 may include the first portion 111_1 and the second portion 111_2 which has a different shape from a shape of the first portion 111_1. For example, the second portion 111_2 may have a greater thickness so that a physical distance between the first gate electrode 121 and the substrate 100 may increase. As the physical distance increases, it may become easier to block leakage current.

A first trench t1 may be disposed in the substrate 100, the first gate insulating film 111, and the first gate electrode 121. The liner film 140 may extend along at least a portion of a side surface of the first gate insulating film 111. The liner film 140 may be spaced apart from a lower surface t1_b of the first trench t1. In other words, the liner film 140 may not be disposed on the lower surface t1_b of the first trench t1. A length from the upper surface 121u of the first gate electrode 121 to the lower surface t1_b of the first trench t1 may be defined as a first length S1.

A lower width W1 and an upper width W2 of the first trench t1 may be different from each other. For example, the lower width W1 of the first trench t1 may be smaller than the upper width W2 thereof. For example, the first trench t1 may include a shape in which a width decreases as the first trench t1 extends in a direction from a top to a bottom. However, some example embodiments of the present disclosure are not limited thereto.

The liner film 140 may entirely cover a sidewall 111s of the first gate insulating film 111. The liner film 140 may entirely cover a sidewall 121s of the first gate electrode 121. The liner film 140 may cover a portion of a sidewall 100s of the substrate 100.

At least a portion of the first gate insulating film 111 in the first area I may be covered with the liner film 140. Accordingly, damage to the first gate insulating film 111 that may occur during a subsequent process may be prevented or reduced in likelihood.

A lower surface 140b of the liner film 140 may be disposed between the lowermost surface 111_2b of the second portion 111_2 and the lower surface t1_b of the first trench t1. An upper surface 140u of the liner film 140 may be coplanar with the upper surface 121u of the first gate electrode 121.

A step 105 may be formed between the liner film 140 and the substrate 100. The step 105 may be formed due to a shape in which the liner film 140 protrudes from the substrate 100 toward the first trench t1. For example, the step 105 may be formed between the lowermost surface 111_2b of the second portion 111_2 and the lower surface t1_b of the first trench t1.

The liner film 140 may include an oxide film. For example, the liner film 140 may include, but is not limited to, a silicon oxide film. Although a boundary between the liner film 140 and the first gate insulating film 111 is shown as being visible, some example embodiments of the present disclosure is not limited thereto. For example, the boundary between the liner film 140 and the first gate insulating film 111 may be ambiguous.

The insulating layer 130 may include a first insulating layer 131 and a second insulating layer 132. The first insulating layer 131 may be disposed on the upper surface 121u of the first gate electrode 121. The second insulating layer 132 may fill the trenches t1, t2, and t3. Although the insulating layer 130 is shown as a single layer, some example embodiments of the present disclosure are not limited thereto. For example, the insulating layer 130 may include two or more layers.

The second gate insulating film 112 may be disposed in the second area II of the substrate 100. The second gate electrode 122 may be disposed on the second gate insulating film 112. In other words, the second gate insulating film 112 may be disposed between the second gate electrode 122 and the substrate 100.

The second gate insulating film 112 may have a second thickness M2. The second thickness M2 may be smaller than the first thickness M1. The second trench t2 may be disposed in the substrate 100, the second gate insulating film 112, and the second gate electrode 122. A length from the upper surface 122u of the second gate electrode 122 to a lower surface t2_b of the second trench t2 may be defined as a second length S2. The second length S2 may be smaller than the first length S1.

The first insulating layer 131 may be disposed on the upper surface 122u of the second gate electrode 122. The second insulating layer 132 may fill the second trench t2.

The third gate insulating film 113 may be disposed in the third area III of the substrate 100. The third gate electrode 123 may be disposed on the third gate insulating film 113. In other words, the third gate insulating film 113 may be disposed between the third gate electrode 123 and the substrate 100.

The third gate insulating film 113 may have a third thickness M3. The third thickness M3 may be greater than the second thickness M2. The third trench t3 may be disposed in the substrate 100, the third gate insulating film 113, and the third gate electrode 123. A length from the upper surface 123u of the third gate electrode 123 to a lower surface t3_b of the third trench t3 may be defined as a third length S3. The third length S3 may be smaller than the first length S1.

The first insulating layer 131 may be disposed on the upper surface 123u of the third gate electrode 123. The second insulating layer 132 may fill the third trench t3.

The lower surface 111b of the first portion 111_1 of the first gate insulating film 111 and the lower surface 113b of the third gate insulating film 113 may be coplanar with each other. The lower surface 112b of the second gate insulating film 112 may not be coplanar with the lower surface 111b of the first portion 111_1 of the first gate insulating film 111. The lower surface 112b of the second gate insulating film 112 may not be coplanar with the lower surface 113b of the third gate insulating film 113.

Each of the first to third gate insulating films 111, 112, and 113 may include, for example, silicon oxide or a high dielectric constant material (e.g., aluminum oxide (Al₂O₃)) or hafnium oxide (HfO₂).

Each of the first to third gate electrodes 121, 122, and/or 123 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. The present disclosure is not limited thereto.

For example, the insulating layer 130 may include at least one of silicon oxide, silicon nitride, silicon oxynitride, and/or a low-k material with a lower dielectric constant than that of silicon oxide. The low dielectric constant material may include, for example, FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and/or combinations thereof. However, some example embodiments of the present disclosure are not limited thereto.

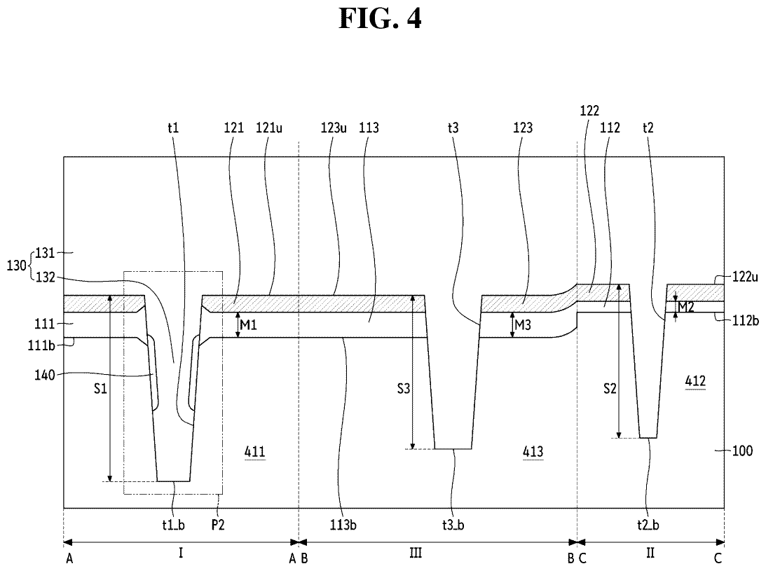

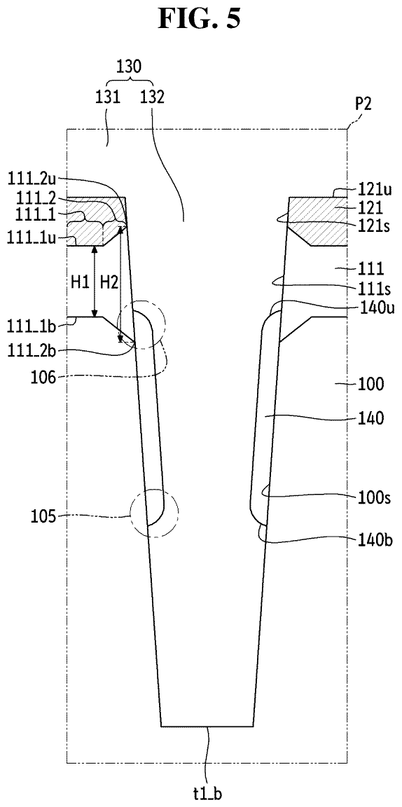

FIG. 4 is a schematic cross-sectional view cut along lines A-A, B-B, and C-C of FIG. 1 according to some example embodiments. FIG. 5 is an enlarged cross-sectional view of a P2 area in FIG. 4. For convenience of description, contents duplicate with those described above using FIGS. 1 to 3 are briefly described or descriptions thereof are omitted.

Referring to FIG. 4 and FIG. 5, the liner film 140 may cover a portion of a sidewall 111s of the first gate insulating film 111. The liner film 140 may not cover a sidewall 121s of the first gate electrode 121. The liner film 140 may cover a portion of a sidewall 100s of the substrate 100.

The upper surface 140u of the liner film 140 may not be coplanar with the upper surface 121u of the first gate electrode 121. For example, the upper surface 140u of the liner film 140 may be disposed between the lowermost surface 111_2b and the uppermost surface 111_2u of the second portion 111_2.

A first step 105 and a second step 106 may be formed between the liner film 140 and the substrate 100. The first step 105 may be formed due to a shape in which the lower surface 140b of the liner film 140 protrudes from the substrate 100 toward the first trench t1. The second step 106 may be formed due to a shape in which the upper surface 140u of the liner film 140 protrudes from the substrate 100 toward the first trench t1.

For example, the first step 105 may be formed between the lowermost surface 111_2b of the second portion 111_2 and the lower surface t1_b of the first trench t1. The second step 106 may be formed between the lowermost surface 111_2b of the second portion 111_2 and the uppermost surface 111_2u of the second portion 111_2.

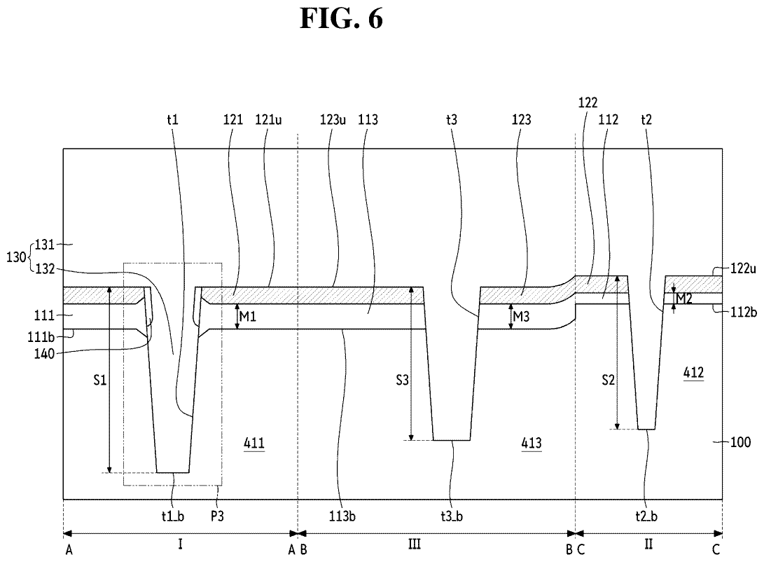

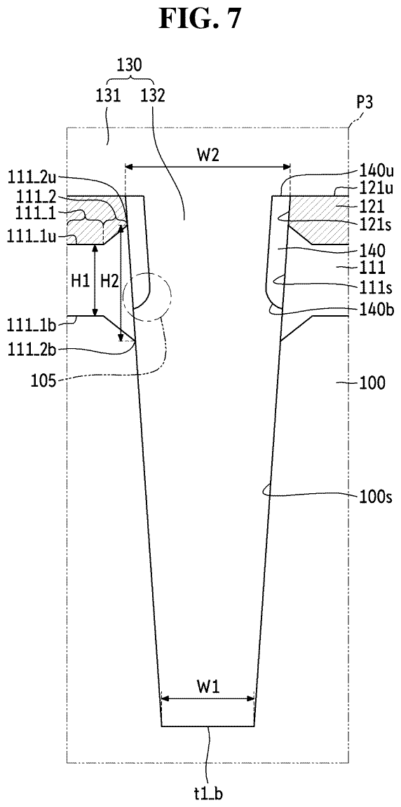

FIG. 6 is a schematic cross-sectional view cut along lines A-A, B-B, and C-C of FIG. 1 according to still some other example embodiments. FIG. 7 is an enlarged cross-sectional view of a P3 area in FIG. 6. For convenience of description, contents duplicate with those described above using FIGS. 1 to 3 are briefly described or descriptions thereof are omitted.

Referring to FIG. 6 and FIG. 7, the liner film 140 may cover a portion of a sidewall 111s of the first gate insulating film 111. The liner film 140 may entirely cover a sidewall 121s of the first gate electrode 121. The liner film 140 may not cover a sidewall 100s of the substrate 100.

The lower surface 140b of the liner film 140 may be disposed between the lowermost surface 111_2b of the second portion 111_2 and the uppermost surface 111_2u of the second portion 111_2. The upper surface 140u of the liner film 140 may be coplanar with the upper surface 121u of the first gate electrode 121.

The step 105 may be formed between the liner film 140 and the substrate 100. The step 105 may be formed due to a shape in which the liner film 140 protrudes from the substrate 100 toward the first trench t1. For example, the step 105 may be formed between the lowermost surface 111_2b of the second portion 111_2 and the uppermost surface 111_2u of the second portion 111_2.

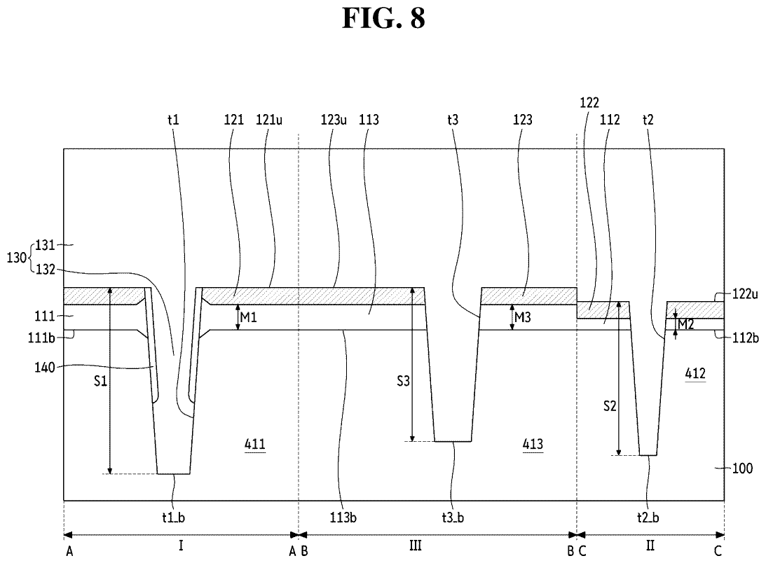

FIG. 8 is a schematic cross-sectional view cut along lines A-A, B-B, and C-C of FIG. 1 according to still yet some other example embodiments. For convenience of description, contents duplicate with those described above using FIGS. 1 to 3 are briefly described or descriptions thereof are omitted.

Referring to FIG. 8, the lower surface 111b of the first portion 111_1 of the first gate electrode 121, the lower surface 112b of the second gate electrode 122, and the lower surface 113b of the third gate electrode 123 may be coplanar with each other.

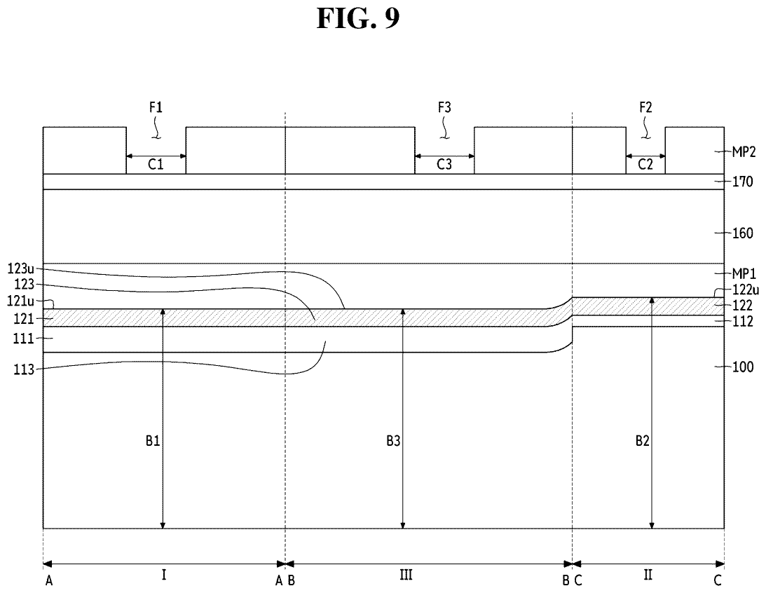

FIGS. 9 to 17 are diagrams of intermediate structures corresponding to intermediate steps of a method for manufacturing a semiconductor device according to some example embodiments.

Referring to FIG. 9, the substrate 100 including the first area I, the second area II, and the third area III is provided.

On the first area I, the first gate insulating film 111, the first gate electrode 121, a first mask MP1, a first sacrificial film 160, a second sacrificial film 170, and a second mask MP2 may be sequentially stacked. On the second area II, the second gate insulating film 112, the second gate electrode 122, the first mask MP1, the first sacrificial film 160, the second sacrificial film 170, and the second mask MP2 may be sequentially stacked. On the third area III, the third gate insulating film 113, the third gate electrode 123, the first mask MP1, the first sacrificial film 160, the second sacrificial film 170, and the second mask MP2 may be sequentially stacked.

The second mask MP2 may include a first opening F1 on the first area I, a second opening F2 on the second area II, and a third opening F3 on the third area III. A width C1 of the first opening F1 may be equal to a width C3 of the third opening F3. A width C2 of the second opening F2 may be smaller than each of the width C1 of the first opening F1 and the width C3 of the third opening F3.

A vertical dimension B1 between the upper surface 121u of the first gate electrode 121 and a bottom of the substrate 100 in the first area I may be equal to a vertical dimension B3 between the upper surface 123u of the third gate electrode 123 and a bottom of the substrate 100 in the third area III. In other words, the upper surface 121u of the first gate electrode 121 and the upper surface 123u of the third gate electrode 123 may be coplanar with each other.

A vertical dimension B2 between the upper surface 122u of the second gate electrode 122 and a bottom of the substrate 100 in the second area II may be greater than the vertical dimension B1 between the upper surface 121u of the first gate electrode 121 and a bottom of the substrate 100 in the first area I. The vertical dimension B2 between the upper surface 122u of the second gate electrode 122 and a bottom of the substrate 100 in the second area II may be greater than the vertical dimension B3 between the upper surface 123u of the third gate electrode 123 and a bottom of the substrate 100 in the third area III.

The first mask MP1 may include, for example, polyethylene oxide (PEO). However, some example embodiments of the present disclosure are not limited thereto. The first sacrificial film 160 may include at least one of a carbon-containing material or a metal. For example, the first sacrificial film 160 may be made of a spin-on hardmask (SOH). The second sacrificial film 170 may act as an antireflection film. The second mask MP2 may include, for example, a photoresist.

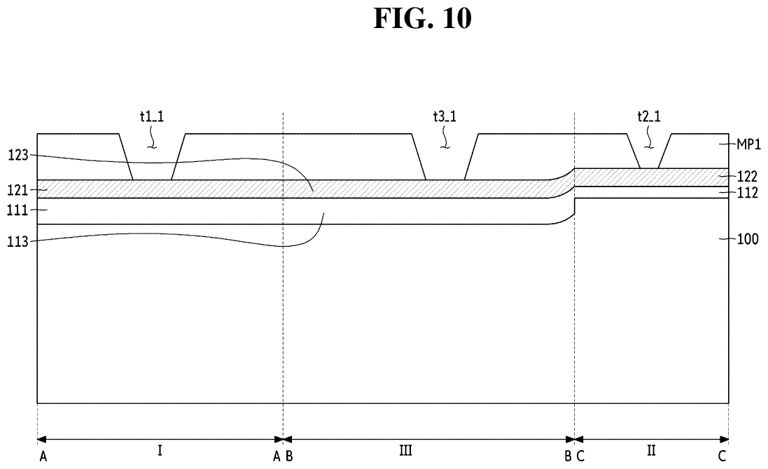

Referring to FIG. 10, a first-first trench t1_1, a first-second trench t2_1, and a first-third trench t3_1 are formed in the first mask MP1 using the second mask MP2. After forming the trench in the first mask MP1, the first sacrificial film 160, the second sacrificial film 170, and the second mask MP2 may be removed.

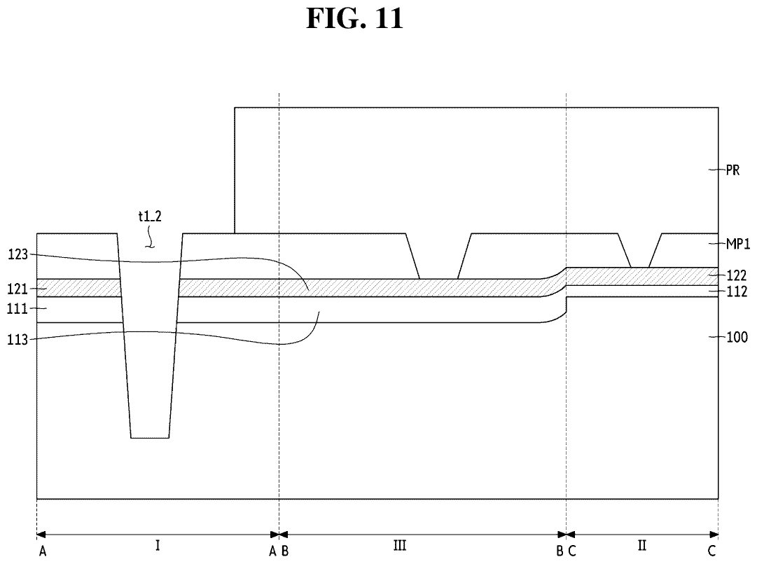

Referring to FIG. 11, a photoresistor PR may be formed on the second area II and the third area III. As a result, only a portion of the first mask MP1 in the first area I may be exposed.

An etching process may be performed on the first area I using the first mask MP1. A second-first trench t1_2 may be formed by the etching process performed only on the first area I.

The second-first trench t1_2 may be deeper than the first-first trench t1_1 as shown in FIG. 10.

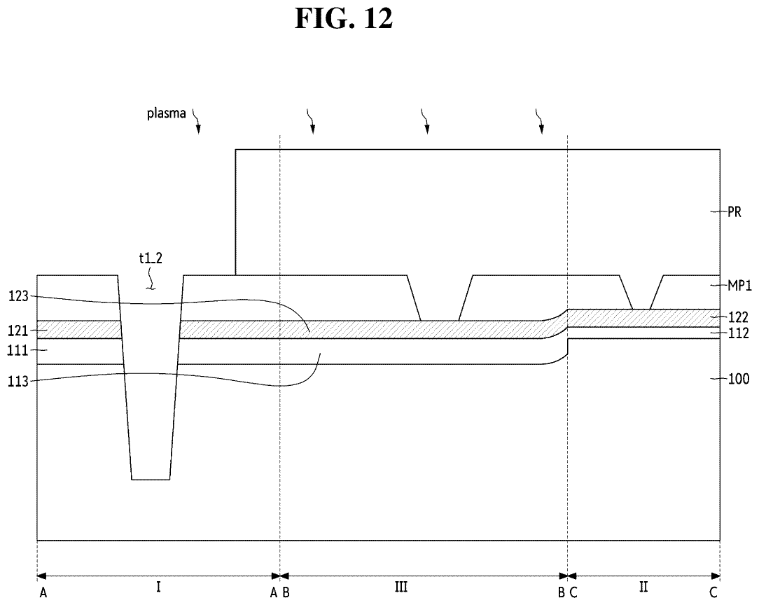

Referring to FIG. 12, a plasma process may be performed in a state in which the photoresist PR has been formed on the second area II and the third area III. For reference, the second area II and the third area III may not be exposed to plasma while being covered with the photoresist PR.

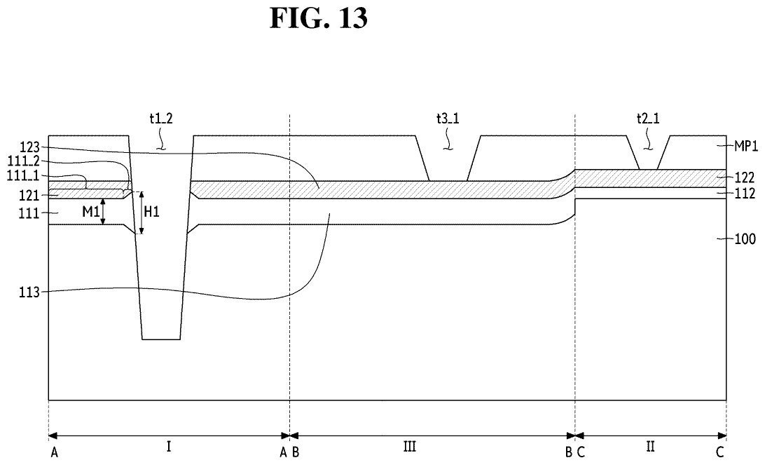

Referring to FIG. 13, the photoresist (PR in FIG. 12) formed on the second area II and third area III may be removed. Accordingly, the first-second trench t2_1 and the first-third trench t3_1 may be exposed.

In the plasma process as shown in FIG. 12, the first portion 111_1 and the second portion 111_2 may be formed in the first gate insulating film 111 on the first area I. The first portion 111_1 may be disposed to be spaced apart from the second-first trench t1_2. The second portion 111_2 may be disposed to be exposed to the second-first trench t1_2. The thickness H1 of the second portion 111_2 may be greater than the thickness M1 of the first portion 111_1. The thickness H1 of the second portion 111_2 may increase as the second portion 111_2 extends toward the second-first trench t1_2.

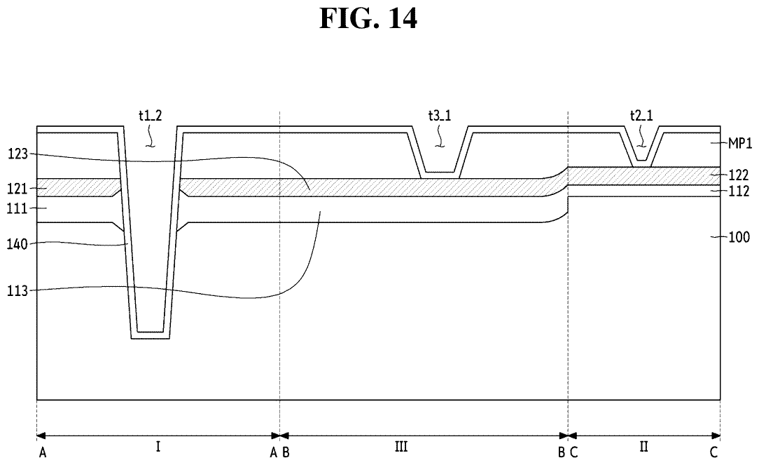

Referring to FIG. 14, the liner film 140 may be formed on the second-first trench t1_2, the first-second trench t2_1, the first-third trench t3_1, and the first mask MP. The liner film 140 may be formed along a profile of each of the trenches. For example, the liner film 140 may include an oxide film.

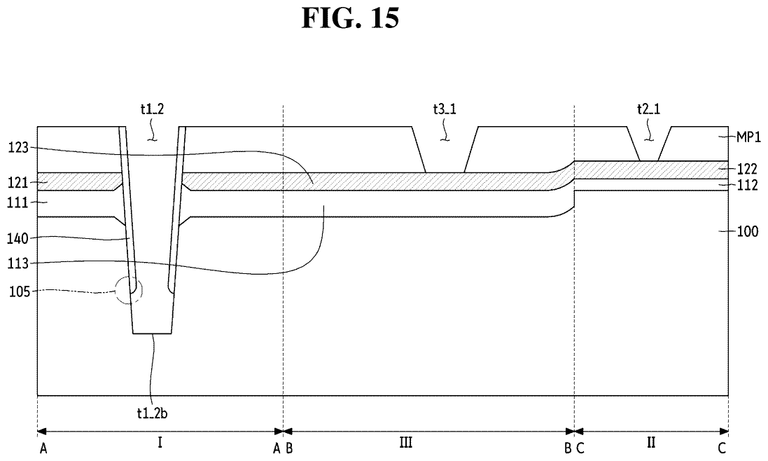

Referring to FIG. 15, a portion of the liner film 140 may be removed. A portion of the liner film 140 formed in the second-first trench t1_2 remains, and a portion of the liner film 140 disposed on a lower surface t1_2b of the second-first trench t1_2 may be removed. As the portion of the liner film 140 is removed and the portion thereof remains, the step 105 may be formed between the liner film 140 and the substrate 100.

A portion of the liner film 140 formed in the first-second trench t2_1 and a portion of the liner film 140 formed in the first-third trench t3_1 are shown as removed. However, some example embodiments of the present disclosure are not limited thereto. For example, a portion of the liner film 140 formed in the first-second trench t2_1 and a portion of the liner film 140 formed in the first-third trench t3_1 may remain. A portion of the liner film 140 formed on the first mask MP1 may be removed.

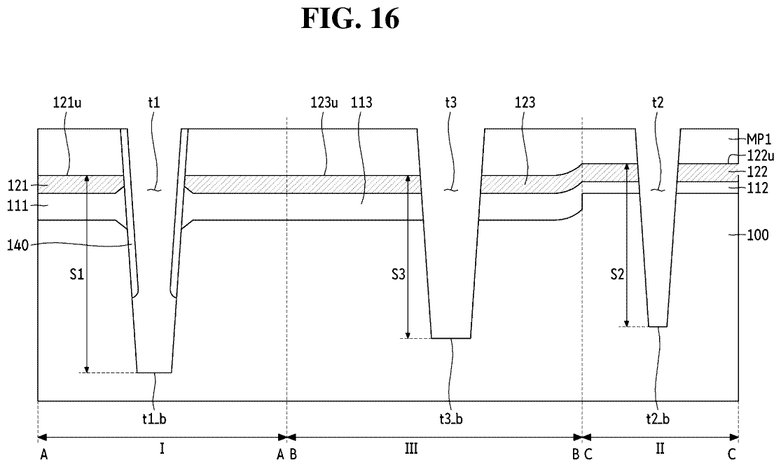

Referring to FIG. 16, an etching process may be performed on the first area I, the second area II, and the third area III. The etching process may be performed to form the first trench t1 in the first area I, the second trench t2 in the second area II, and the third trench t3 in the third area III.

A length from the upper surface 121u of the first gate electrode 121 to the lower surface t1_b of the first trench t1 may be defined as the first length S1. A length from the upper surface 122u of the second gate electrode 122 to the lower surface t2_b of the second trench t2 may be defined as the second length S2. A length from the upper surface 123u of the third gate electrode 123 to the lower surface t3_b of the third trench t3 may be defined as the third length S3.

The second length S2 may be smaller than the first length S1. The third length S3 may be smaller than the first length S1. The second length S2 may be equal to the third length S3.

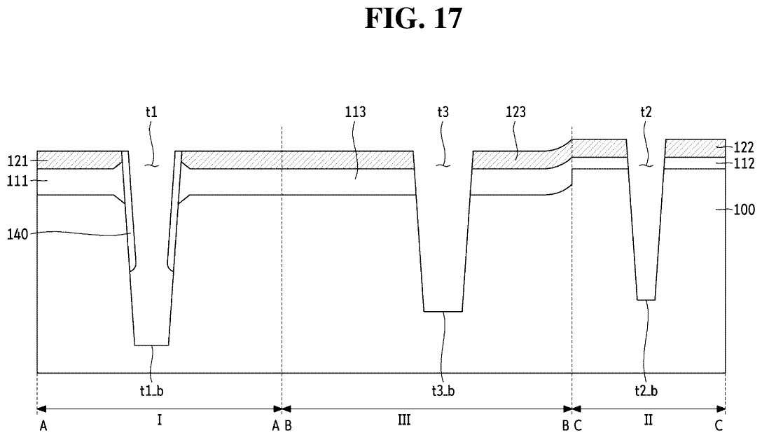

Referring to FIG. 17, the first mask MP1 may be removed.

Next, referring to FIG. 2, the insulating layer 130 may be formed to fill the first trench t1, the second trench t2, and the third trench t3, and to cover the upper surfaces 121u, 122u, and 123u of the gate electrodes 121, 122, and 123.

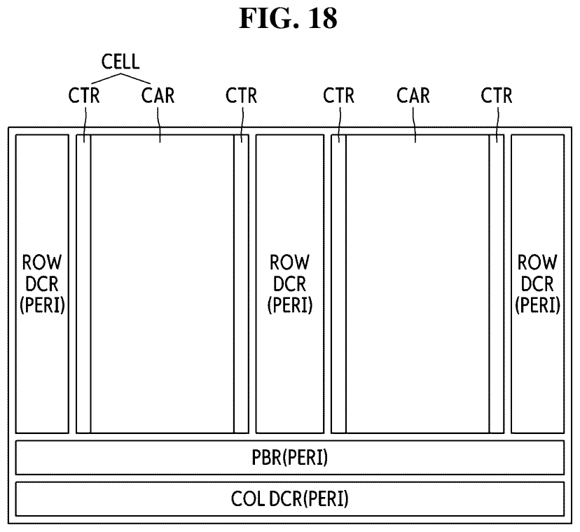

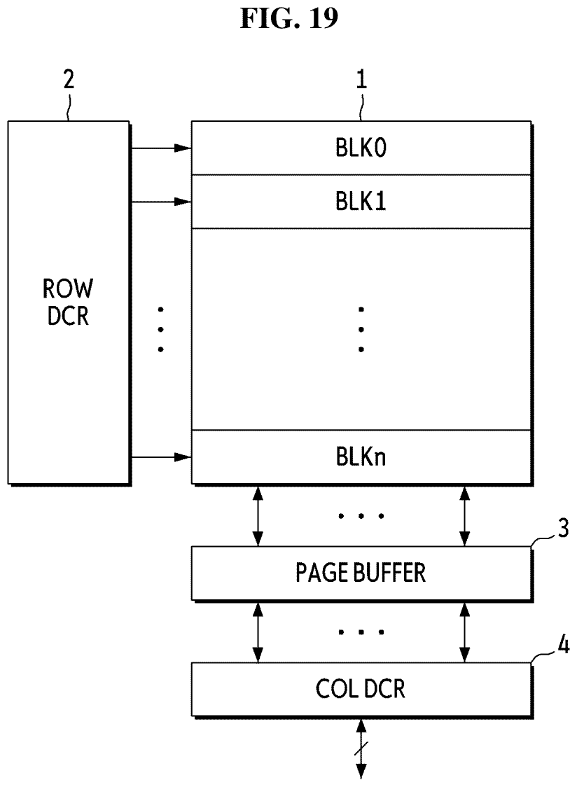

FIG. 18 is a schematic plan view for illustrating a non-volatile memory device according to some example embodiments of the technical idea of the present disclosure. FIG. 19 is a block diagram for illustrating the non-volatile memory device in FIG. 18.

Referring to FIG. 18 and FIG. 19, a non-volatile memory device according to some example embodiments may include a cell area CELL and a peripheral circuit area PERI. The peripheral circuit area PERI may include row decoder areas ROW DCR, a page buffer area PBR, and a column decoder area COL DCR.

The cell area CELL may include a cell array area CAR and a contact area CTR.

A memory cell array 1 including a plurality of memory cells may be formed in the cell array area CAR. The memory cell array 1 may include a plurality of memory cells and a plurality of word-lines and a plurality of bit-lines electrically connected to the memory cells. In some example embodiments, the memory cell array 1 may include a plurality of memory blocks BLK0 to BLKn as data erase units.

The contact area CTR may be interposed between the cell array area CAR and the peripheral circuit area PERI. For example, the contact area CTR may be interposed between the cell array area CAR and the row decoder areas ROW DCR.

A row decoder 2 that selects the word-lines of the memory cell array 1 may be disposed in the row decoder area ROW DCR. A contact wiring structure that electrically connects the memory cell array 1 and the row decoder 2 to each other may be formed in the contact area CTR. The row decoder 2 may select one of the memory blocks BLK0 to BLKn of the memory cell array 1 based on address information and select one of the word-lines of the selected memory block. The row decoder 2 may provide a word-line voltage generated from a voltage generation circuit (not shown) to each of the selected word-line and unselected word-lines, in response to control of a control circuit (not shown).

A page buffer 3 for reading information stored in the memory cells may be formed in the page buffer area PBR. Depending on an operation mode, the page buffer 3 may temporarily store therein data to be stored in the memory cells or detect data stored in the memory cells. The page buffer 3 may operate as a write driver circuit in a program operation mode and may operate as a sense amplifier circuit in a read operation mode.

A column decoder 4 connected to the bit-lines of the memory array 1 may be formed in the column decoder area COL DCR. The column decoder 4 may provide a data transmission path between the page buffer 3 and an external device (e.g., a memory controller).

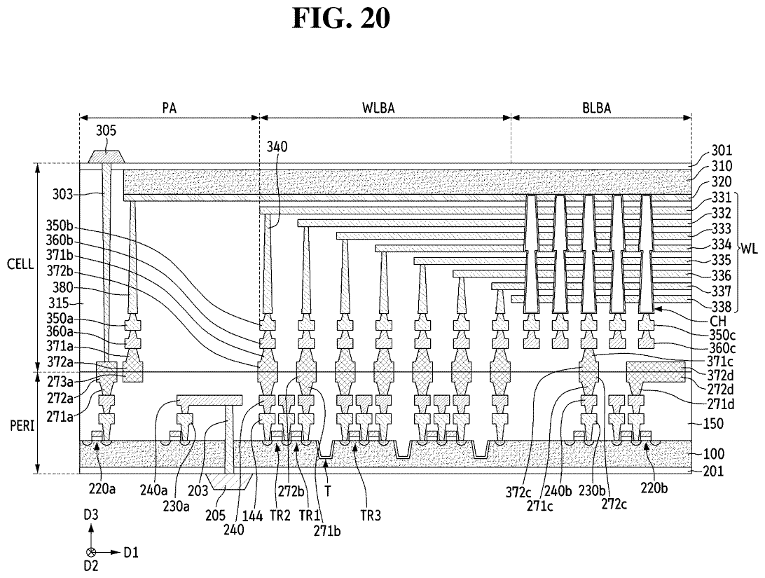

FIG. 20 is a schematic cross-sectional view for illustrating a non-volatile memory device according to some example embodiments. For convenience of description, contents duplicate with those described above using FIGS. 1 to 8 are briefly described or descriptions thereof are omitted.

Referring to FIG. 20, a non-volatile memory device according to some example embodiments may include a peripheral circuit area PERI and a cell area CELL.

Each of the peripheral circuit area PERI and the cell area CELL may include an external pad bonding area PA, a word-line bonding area WLBA, and a bit-line bonding area BLBA.

The word-line bonding area WLBA may be defined as an area where a plurality of cell contact plugs 340, etc. are disposed. A lower bonding metal 271b and 272b may be formed on a second metal layer 240 of the word-line bonding area WLBA. In the word-line bonding area WLBA, the lower bonding metal 271b and 272b of the peripheral circuit area PERI may be electrically connected to an upper bonding metal 371b and 372b of the cell area CELL in a bonding manner. Each of the lower bonding metal 271b and 272b and the upper bonding metal 371b and 372b may be made of aluminum, copper, or tungsten. In the word-line bonding area WLBA, the cell contact plugs 340 may be connected to the peripheral circuit area PERI via the upper bonding metal 371b and 372b of the cell area CELL and the lower bonding metal 271b and 272b of the peripheral circuit area PERI.

The bit-line bonding area BLBA may be defined as an area where a channel structure CH and a bit-line 360c are disposed. The bit-line 360c may be electrically connected to a fifth circuit element 220b in the bit-line bonding area BLBA. For example, the bit-line 360c may be connected to the upper bonding metal 371c and 372c in the peripheral circuit area PERI. The upper bonding metal 371c and 372c may be connected to the lower bonding metal 271c and 272c connected to the fifth circuit element 220b.

A common source line contact plug 380 may be disposed in the external pad bonding area PA. The common source line contact plug 380 may be made of a conductive material such as metal, metal compound, or polysilicon, and may be electrically connected to a common source line 320. A first metal layer 350a and a second metal layer 360a may be disposed under the common source line contact plug 380 and may be sequentially stacked. For example, an area where the common source line contact plug 380, the first metal layer 350a, and the second metal layer 360a are disposed may be defined as the external pad bonding area PA. Furthermore, input/output pads 205 and 305 may be disposed in the external pad bonding area PA.

A metal pattern of the uppermost metal layer in each of the external pad bonding area PA and the bit-line bonding area BLBA included in the cell area CELL and peripheral circuit area PERI, respectively may exist as a dummy pattern. Alternatively, the uppermost metal layer in each of the external pad bonding area PA and the bit-line bonding area BLBA included in the cell area CELL and peripheral circuit area PERI, respectively may be empty.

In the non-volatile memory device according to some example embodiments, in the external pad bonding area PA, a lower metal pattern 273a of the same shape as that of an upper metal pattern 372a of the cell area CELL may be formed in the uppermost metal layer of the peripheral circuit area PERI in a corresponding manner to the upper metal pattern 372a formed in the uppermost metal layer of the cell area CELL. The lower metal pattern 273a formed in the uppermost metal layer of the peripheral circuit area PERI may not be connected to a separate contact in the peripheral circuit area PERI. Similarly, in the external pad bonding area PA, an upper metal pattern of the same shape as that of a lower metal pattern of the peripheral circuit area PERI may be formed in the upper metal layer of the cell area CELL in a corresponding manner to the lower metal pattern formed in the uppermost metal layer of the peripheral circuit area PERI.

Furthermore, in the bit-line bonding area BLBA, an upper metal pattern 372d of the same shape as that of a lower metal pattern 272d of the peripheral circuit area PERI may be formed in the uppermost metal layer of the cell area CELL in a corresponding manner to the lower metal pattern 272d formed in the uppermost metal layer of the peripheral circuit area PERI. A contact may not be formed on the upper metal pattern 372d formed in the uppermost metal layer of the cell area CELL.

The peripheral circuit area PERI may include a first substrate 100, an interlayer insulating film 150, a plurality of circuit elements TR1, TR2, TR3, 220a, and 220b formed in the first substrate 100, a first metal layer 144, 230a, and 230b connected to each of the plurality of circuit elements TR1, TR2, TR3, 220a, and 220b, and a second metal layer 240 240a, and 240b formed on the first metal layer 144, 230a, and 230b.

The first circuit element (see TR1 in FIG. 1) may be electrically connected to the word-line WL. For example, a first area (see the first area I in FIG. 1) where the first circuit element TR1 is located may correspond to the row decoder area ROW DCR in FIG. 18. The first circuit element TR1 may provide the row decoder (see the row decoder 2 in FIG. 19) in the peripheral circuit area PERI.

The third circuit element TR3 may be electrically connected to the bit-line BL. For example, a third area (see the third area III in FIG. 1) where the third circuit element TR3 is disposed may correspond to the page buffer area PBR in FIG. 18. The third circuit element TR3 may provide the page buffer (see the page buffer 3 in FIG. 19) in the peripheral circuit area PERI.

The second circuit element TR2 may be disposed in at least one of the first area I and the second area II. The second circuit element TR2 may be disposed in an area other than the first area I and the second area II.

A trench T may be one of the first trench t1, the second trench t2, and the third trench t3 shown in FIGS. 1 to 8.

In the present disclosure, only the first metal layer 144, 230a, and 230b and the second metal layer 240, 240a, and 240b are shown and described. However, some example embodiments of the present disclosure are not limited thereto. At least one additional metal layer may be formed on the second metal layer 240, 240a, and 240b. At least some of the one or more metal layers formed on the second metal layers 240, 240a, and 240b may be made of aluminum, etc., which has a lower resistance than that of the copper constituting the second metal layer 240, 240a, and 240b.

In some example embodiments, the first metal layer 144, 230a, and 230b may be made of tungsten with a relatively high resistance, and the second metal layer 240, 240a, and 240b may be made of copper with a relatively low resistance.

The interlayer insulating film 150 may be disposed on the first substrate 100 so as to cover the plurality of circuit elements TR1, TR2 and TR3, 220a, and 220b, the first metal layer 144, 230a, and 230b, and the second metal layer 240, 240a, and 240b.

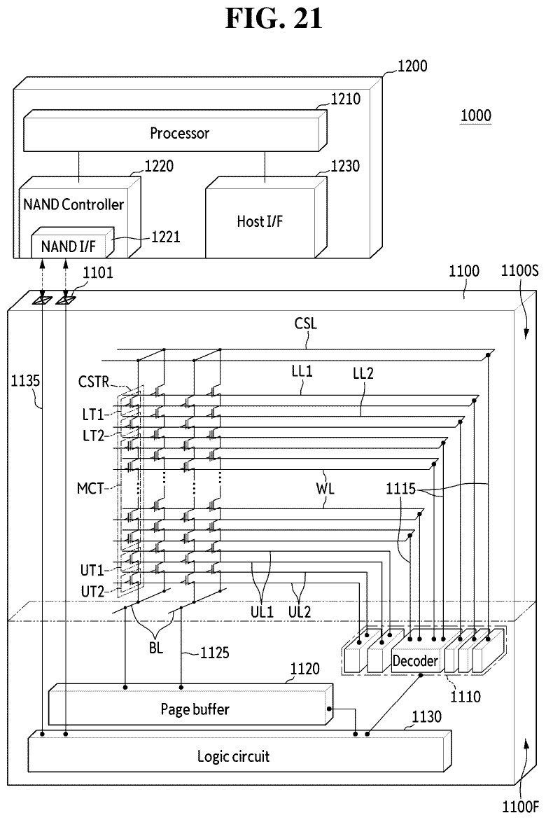

The cell area CELL may provide at least one memory block. The cell area CELL may include a second substrate 310 and the common source line 320. On the second substrate 310, a plurality of word-lines 331 to 338 WL may be stacked along a vertical direction Z that intersects an upper surface of the second substrate 310. A string select line (e.g., UL1, UL2 in FIG. 21) and a ground select line (e.g., LL1, LL2 in FIG. 21) may be disposed on top of and under the word-lines WL, respectively. The plurality of word-lines WL may be disposed between the string select line and the ground select line.

The channel structure CH may extend in the vertical direction and extend through the word-lines WL, the string select lines, and the ground select line. The common source line 320 may be formed to contact a semiconductor pattern of the channel structure CH.

The word-lines WL may extend along a direction (e.g., the first direction X) parallel to the upper surface of the second substrate 310, and may be connected to a plurality of cell contact plugs 340. The word-lines WL and the cell contact plugs 340 may be connected to each other via pads formed by extending at least some of the word-lines WL by different lengths. A first metal layer 350b and a second metal layer 360b may be sequentially stacked and may be disposed under each of the cell contact plugs 340 connected to the word-lines WL and may be connected to a bottom of each of the cell contact plugs 340 connected to the word-lines WL.

In some example embodiments, a lower insulating film 201 covering a lower surface of the first substrate 100 may be formed under the first substrate 100, and a first input/output pad 205 may be formed on the lower insulating film 201. The first input/output pad 205 may be connected to at least one of the plurality of circuit elements TR1, TR2, TR3, 220a, and 220b disposed in the peripheral circuit area PERI via a first input/output contact plug 203 and may be insulated from the first substrate 100 via a lower insulating film 201. Furthermore, a side insulating film may be disposed between the first input/output contact plug 203 and the first substrate 100 so as to electrically insulate the first input/output contact plug 203 from the first substrate 100.

In some example embodiments, an upper insulating film 301 covering the upper surface of the second substrate 310 may be formed on top of the second substrate 310, and a second input/output pad 305 may be disposed on the upper insulating film 301. The second input/output pad 305 may be connected to at least one of the plurality of circuit elements TR1, TR2, TR3, 220a, and 220b disposed in the peripheral circuit area PERI via a second input/output contact plug 303.

In some example embodiments, the second substrate 310 and the common source line 320 may not be disposed in an area where the second input/output contact plug 303 is disposed. Furthermore, the second input/output pad 305 may not overlap the word-lines WL in the vertical direction Z. The second input/output contact plug 303 may be insulated from the second substrate 310 in a direction (e.g., the first direction X) parallel to the upper surface of the second substrate 310 and may extend through the interlayer insulating film 315 in the cell area CELL so as to be connected to the second input/output pad 305.

In some example embodiments, the first input/output pad 205 and the second input/output pad 305 may be optionally formed. For example, the non-volatile memory device according to some example embodiments may include only the first input/output pad 205 disposed on the first substrate 100, or may include only the second input/output pad 305 disposed on the second substrate 310. Alternatively, the non-volatile memory device according to some example embodiments may include both the first input/output pad 205 and the second input/output pad 305.

FIG. 21 is a schematic block diagram for illustrating an electronic system according to some example embodiments.

FIG. 21 is a diagram schematically showing an electronic system including a semiconductor device according to some example embodiments of the present disclosure.

Referring to FIG. 21, an electronic system 1000 according to some example embodiment of the present disclosure may include a semiconductor device 1100 and a controller 1200 electrically connected to the semiconductor device 1100. The electronic system 1000 may be a storage device including one or a plurality of semiconductor devices 1100 or may be an electronic device including the storage device. For example, the electronic system 1000 may be a solid state drive (SSD) device, a universal serial bus (USB) device, a computing system, a medical device, or a communication device including one or a plurality of semiconductor devices 1100.

The semiconductor device 1100 may be a non-volatile memory device, for example, a NAND flash memory device as described above with reference to FIGS. 1 to 20. The semiconductor device 1100 may include a first structure 110F and a second structure 1100S disposed on the first structure 110F. In some example embodiments, the first structure 110F may be disposed next to the second structure 1100S. The first structure 110F may be a peripheral circuit structure including a decoder circuit 1110, a page buffer 1120, and a logic circuit 1130. The second structure 1100S may be a memory cell structure including a bit-line BL, common source line CSL, word-lines WL, first and second gate upper lines UL1 and UL2, first and second gate lower lines LL1 and LL2, and memory cell strings CSTR between the bit-line BL and the common source line CSL.

In the second structure 1100S, each memory cell string CSTR may include lower transistors LT1 and LT2 adjacent to the common source line CSL, upper transistors UT1 and UT2 adjacent to the bit-line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on the example embodiments.

In some example embodiments, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2, respectively. The word-lines WL may be gate electrodes of the memory cell transistors MCT, respectively. The gate upper lines UL1 and UL2 may be gate electrodes of the upper transistors UT1 and UT2, respectively.

The common source line CSL, the first and second gate lower lines LL1 and LL2, the word-lines WL, and the first and second gate upper lines UL1 and UL2 may be electrically connected to the decoder circuit 1110 via first connection wirings 1115 extending in the first structure 110F to the second structure 1100S. The bit-lines BL may be electrically connected to the page buffer 1120 via second connection wirings 1125 extending in the first structure 110F to the second structure 1100S.

In the first structure 110F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1000 may communicate with a controller 1200 via an input/output pad 1101 that is electrically connected to the logic circuit 1130. The input/output pad 1101 may be electrically connected to the logic circuit 1130 via an input/output connection wiring 1135 extending in the first structure 110F to the second structure 1100S.

The controller 1200 may include a processor 1210, a NAND controller 1220, and a host interface 1230. Depending on some example embodiments, the electronic system 1000 may include a plurality of semiconductor devices 1100. In this case, the controller 1200 may control the plurality of semiconductor devices 1000.

The processor 1210 may control overall operations of the electronic system 1000 including the controller 1200. The processor 1210 may operate based on predefined firmware, and may control the NAND controller 1220 to access the semiconductor device 1100. The NAND controller 1220 may include a NAND interface 1221 that processes communication with the semiconductor device 1100. Via the NAND interface 1221, a control command for controlling the semiconductor device 1100, data to be written to memory cell transistors MCT of the semiconductor device 1100, and data to be read from the memory cell transistors MCT of the semiconductor device 1100 may be transmitted. The host interface 1230 may provide a communication function between the electronic system 1000 and an external host. Upon receiving a control command from an external host via the host interface 1230, the processor 1210 may control the semiconductor device 1100 in response to the control command.

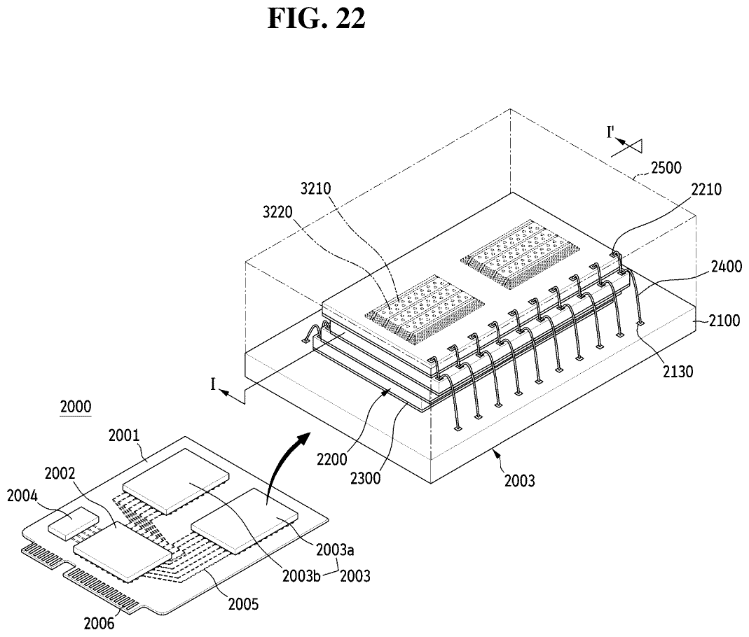

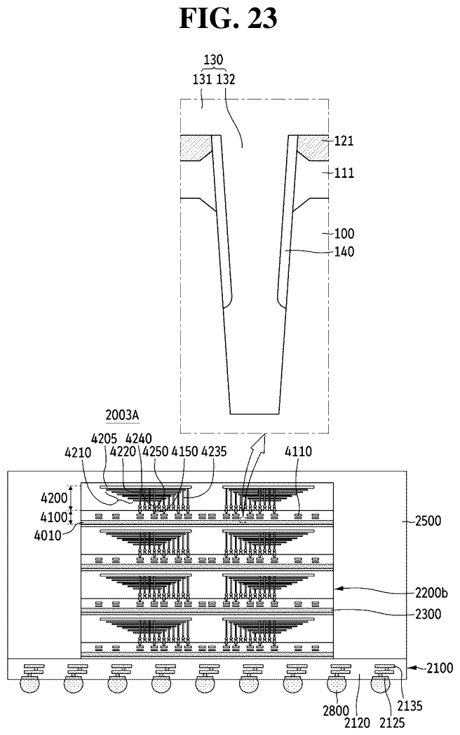

FIG. 22 is a schematic perspective view for illustrating an electronic system according to some example embodiments. FIG. 23 shows various schematic cross-sectional views cut along a line I-I′ in FIG. 22. For convenience of description, contents duplicate with those described above using FIGS. 1 to 21 are briefly described or descriptions thereof are omitted.

Referring to FIG. 22, an electronic system according to some example embodiments may include a main substrate 2001, a main controller 2002 mounted on the main substrate 2001, at least one semiconductor package 2003, and at least one DRAM 2004. The semiconductor package 2003 and he DRAM 2004 may be connected to the main controller 2002 via line patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some example embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some example embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 in FIG. 21. Each of the semiconductor chips 2200 may include memory blocks 3210 and channel structures 3220. The memory block 3210 may correspond to the memory block in FIG. 20, and the channel structure 3220 may correspond to the channel structure CH in FIG. 20.

In some example embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some example embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 and the semiconductor chips 2200 may be connected to each other via a line formed in the interposer substrate.

Referring to FIG. 23, in the semiconductor package 2003A, the package substrate 2100 may be a printed circuit board. The package substrate 2100 may include a package substrate body portion 2120, lower pads 2125 placed on the lower face of the package substrate body portion 2120 or exposed through the lower face, and internal wirings 2135.

The lower pads 2125 may be connected to the wiring patterns 2005 of the main substrate 2100 of the electronic system 2000 through the conductive connections 2800, as in FIG. 22.

Each of the semiconductor chips 2200b may include a semiconductor substrate 4010, a first structure 4100 on the semiconductor substrate 4010, and a second structure 4200 disposed on the first structure 4100 and bonded to the first structure 4100 in a wafer bonding manner.

The first structure 4100 may include a peripheral circuit area including peripheral wiring 4110 and first bond structures 4150. The second structure 4200 may include a common source line 4205, a gate stack structure 4210 between the common source line 4205 and the first structure 4100, memory channel structures 4220 and an isolation structure (not depicted) extending through the gate stack structure 4210, and second bond structures 4250 electrically connected to the memory channel structures 4220 and the word-lines (WL in FIG. 21) of the gate stack structure 4210, respectively. For example, the second bond structures 4250 may be electrically connected to the memory channel structures 4220 and the word-lines (WL in FIG. 21), respectively, via the bit-lines 4240 electrically connected to the memory channel structures 4220 and gate connection wirings 4235 electrically connected to the word-lines (WL in FIG. 21). The first bond structures 4150 of the first structure 4100 and the second bond structures 4250 of the second structure 4200 may be bonded to each other while contacting each other. A bonded portion of each of the first bond structures 4150 and the second bond structures 4250 may be made of, for example, copper (Cu).

Each of the semiconductor chips 2200b may further include an input/output pad (2210 in FIG. 22) that is electrically connected to the peripheral wirings 4110 of the first structure 4100.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

According to some of the aforementioned example embodiments, contact structures in contact with the contact regions of the gate electrodes may be formed by the process of forming a contact structure without a step process for forming the contact regions of the gate electrodes in a step shape. In this case, in a semiconductor device having a stack structure having multiple stages, contact structures having a bent portion at the same level as the bent portion of the channel structure corresponding to each stage may be formed. That is, in the process for forming channel holes of the channel structure, the contact holes of the contact structure may be formed simultaneously, such that the depth of the contact hole etched at one time may be significantly reduced. Accordingly, defects such as short circuits due to expansion of the contact holes due to the formation of a relatively deep contact hole may be prevented or reduced in likelihood.

Although some example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above is not restrictive but illustrative in all respects.

In concluding the detailed description, those skilled in the art will appreciate that many variations and modifications may be made to the example embodiments without substantially departing from the principles of the present inventive concept. Therefore, the disclosed example embodiments of the disclosure are used in a generic and descriptive sense only and not for purposes of limitation.

What is claimed is:

1. A semiconductor device comprising:
a substrate;
a gate electrode on the substrate;
a gate insulating film between the substrate and the gate electrode;
a trench defined within the substrate, the gate insulating film, and the gate electrode;
a liner film within the trench and extending along at least a portion of a side surface of the gate insulating film, wherein the liner film is spaced apart from a lower surface of the trench; and
an insulating layer filling the trench and covering an upper surface of the gate electrode, wherein,
the gate insulating film includes a first portion spaced apart from the liner film and a second portion adjacent to the liner film,
a thickness of the second portion is greater than a thickness of the first portion.

2. The semiconductor device of claim 1, wherein a lower surface of the liner film is between a lowermost surface of the second portion and the lower surface of the trench.

3. The semiconductor device of claim 1, wherein an upper surface of the liner film is coplanar with an upper surface of the gate electrode.

4. The semiconductor device of claim 1, wherein the liner film includes an oxide film.

5. The semiconductor device of claim 1, wherein the thickness of the second portion increases as the second portion extends toward the liner film.

6. The semiconductor device of claim 1, wherein a lowermost surface of the second portion is between a lower surface of the first portion and the lower surface of the liner film.

7. The semiconductor device of claim 1, wherein an uppermost surface of the second portion is between an upper surface of the first portion and an upper surface of the liner film.

8. The semiconductor device of claim 1, further comprising:
a step between the liner film and the substrate.

9. The semiconductor device of claim 1, wherein
a vertical level of an uppermost surface of the second portion is higher than a vertical level of an upper surface of the first portion, and
a vertical level of a lowermost surface of the second portion is lower than a vertical level of a lower surface of the first portion.

10. A semiconductor device comprising:
a substrate including a first area and a second area;
a first gate electrode on the first area;
a first gate insulating film having a first thickness and between the substrate and the first gate electrode;
a first trench defined within the substrate, the first gate insulating film, and the first gate electrode;
a liner film within the first trench, and extending along at least a portion of a side surface of the first gate insulating film, wherein the liner film is spaced apart from a lower surface of the first trench;
a second gate electrode on the second area;
a second gate insulating film between the substrate and the second gate electrode and having a second thickness smaller than the first thickness;
a second trench defined within the substrate, the second gate insulating film, and the second gate electrode; and
an insulating layer filling the first trench and the second trench and covering an upper surface of each of the first gate electrode and the second gate electrode,
wherein a first depth of the first trench from an upper surface of the first gate electrode to a bottom surface of the first trench is greater than a second depth of the second trench from an upper surface of the second gate electrode to a bottom surface of the second trench.

11. The semiconductor device of claim 10, wherein a lower surface of the first gate insulating film is closer to a lower surface of the substrate than a lower surface of the second gate insulating film is to the lower surface of the substrate.

12. The semiconductor device of claim 10, wherein
the first gate insulating film includes a first portion spaced apart from the liner film and a second portion adjacent to the liner film,
a thickness of the second portion is greater than a thickness of the first portion.

13. The semiconductor device of claim 12, wherein
a vertical level of an uppermost surface of the second portion is higher than a vertical level of an upper surface of the first portion,
a vertical level of a lowermost surface of the second portion is lower than a vertical level of a lower surface of the first portion.

14. The semiconductor device of claim 12, wherein a lower surface of the liner film is disposed between a lowermost surface of the second portion and the lower surface of the first trench.

15. The semiconductor device of claim 10, wherein
the substrate further includes a third area,
the semiconductor device further includes,
a third gate electrode on the third area of the substrate,
a third gate insulating film between the substrate and the third gate electrode and having a third thickness;
a third trench defined in the substrate, the third gate insulating film, and the third gate electrode; and
an insulating layer filling the third trench and covering an upper surface of the third gate electrode, and
a third thickness is greater than the second thickness and is smaller than the first thickness.

16. The semiconductor device of claim 15, wherein a third depth of the third trench from the upper surface of the third gate electrode to a bottom surface of the third trench is smaller than the first depth of the first trench, and the third depth of the third trench is greater than the second depth of the second trench.

17. The semiconductor device of claim 10, wherein an upper surface of the liner film is coplanar with an upper surface of the first gate electrode.

18. An electronic system comprising:
a main substrate;
a semiconductor memory device on the main substrate and including a cell area and a peripheral circuit area; and
a controller on the main substrate and electrically connected to the semiconductor memory device,
wherein the semiconductor memory device includes:
a first substrate disposed in the cell area,
a plurality of word-lines on the first substrate, and stacked on top of each other and spaced apart from each other;
a channel structure extending in a vertical direction intersecting an upper surface of the first substrate so as to intersect the plurality of word-lines;
a bit-line on the plurality of word-lines and connected to the channel structure;
a second substrate in the peripheral circuit area; and
a peripheral circuit element on the second substrate,
wherein the peripheral circuit element includes,
a gate electrode on the second substrate;
a gate insulating film between the second substrate and the gate electrode;
a trench defined within the second substrate, the gate insulating film, and the gate electrode; and
a liner film within the trench and extending along at least a portion of a side surface of the gate insulating film, wherein the liner film is spaced apart from a lower surface of the trench.

19. The electronic system of claim 18, wherein the peripheral circuit element electrically connects the word-line and the controller to each other.

20. The electronic system of claim 18, wherein the peripheral circuit element electrically connects the bit-line and the controller to each other.
